(19) United States
(12) Patent Application Publication
(10) Pub. No.: US 2023/0336004 A1
(43) Pub. Date: Oct. 19, 2023

(54) Method and System for Determining at Least One Use Parameter for at Least One Rechargeable Battery Pack for Using a Charger Device for Charging User-Exchangeable Rechargeable Battery Packs for Driving at Least One Mobile Device

(71) Applicant: Andreas Stihl AG & Co. KG, Waiblingen (DE)

(72) Inventors: Christian SPINDLER, Stuttgart (DE); Franzeska MOEGLE-HOFACKER, Schwaebisch Gmuend (DE); Christian UHLMANN, Uttenreuth (DE)

(21) Appl. No.: 18/134,368

(22) Filed: Apr. 13, 2023

(30) Foreign Application Priority Data
Apr. 14, 2022 (DE) 10 2022 203 773.1

(51) Int. Cl. H02J 7/00; H01M 10/44; H01M 10/46; G01R 31/387; G01R 31/371

(52) U.S. Cl. CPC H02J 7/0013; H02J 7/0047; H02J 7/00032; H01M 10/441; H01M 10/443; H01M 10/46; G01R 31/387; G01R 31/371

(57) ABSTRACT

A method determines a use parameter for a rechargeable battery pack for using a charger device that charges user-exchangeable rechargeable battery packs for driving a mobile device. A means of transport includes the charger device. The method ascertains state and rated variables of the rechargeable battery packs relating to a possible charging of the rechargeable battery packs by the charger device; ascertains possible use time durations of the rechargeable battery packs for possibly using the charger device relating to a possible charging of the rechargeable battery packs by the charger device; and determines the use parameter for at least one of the rechargeable battery packs for using the charger device by linking the ascertained state and rated variables and the ascertained possible use time durations taking account of a use limit of the charger device.

### CROSS REFERENCE TO RELATED APPLICATION

This application claims priority under 35 U.S.C. § 119 from German Patent Application No. 10 2022 203773.1, filed Apr. 14, 2022, the entire disclosure of which is herein expressly incorporated by reference.

### BACKGROUND AND SUMMARY

The invention relates to a method and a system, in particular in each case, for determining at least one use parameter for at least one rechargeable battery pack for using a charger device for charging user-exchangeable rechargeable battery packs for driving at least one mobile device, wherein a means of transport comprises the charger device.

The problem addressed by the invention is that of providing a method and a system, in particular in each case, for determining at least one use parameter for at least one rechargeable battery pack for using a charger device for charging user-exchangeable rechargeable battery packs for driving at least one mobile device, wherein a means of transport comprises the charger device, in particular wherein the method and the system, in particular in each case, have improved properties.

The invention solves this problem by providing a method and a system described in the independent claims. Advantageous developments and configurations of the invention are described in the dependent claims.

The method according to the invention is designed for determining at least one use parameter for at least one rechargeable battery pack for using a charger device for charging user-exchangeable rechargeable battery packs, in particular in each case, for driving at least one mobile device. A means of transport comprises the charger device. The method comprises the following steps: a) ascertaining, in particular respective and/or actual, state and rated variables of the rechargeable battery packs relating to a, in particular in each case, possible charging of the rechargeable battery packs by means of the charger device; b) ascertaining, in particular respective, possible use time durations of the rechargeable battery packs for possibly using the charger device relating to a possible, in particular the possible, charging of the rechargeable battery packs by means of the charger device; c) determining the, in particular actual, at least one use parameter for at least one of the rechargeable battery packs for, in particular actually, using the charger device for, in particular actually, charging the at least one rechargeable battery pack by means of the charger device by linking the ascertained state and rated variables and the ascertained possible use time durations taking account of at least one, in particular actual, use limit of the charger device.

This enables optimum use of the charger device and/or, in particular consequently, optimum charging of the at least one rechargeable battery pack, in particular during transport by means of the means of transport and/or in the cases in which not all the rechargeable battery packs can be, in particular fully, charged by means of the charger device comprised by the means of transport in the possible use time durations.

In particular, the method, the determining, the using, the charging, the ascertaining and/or the linking can be automatic. Additionally or alternatively, the charging can be wired.

The determining can be determining at least one value of the at least one use parameter. Additionally or alternatively, the determining can be determining use parameters, in particular values of the use parameters and/or for a plurality of the rechargeable battery packs.

The use parameter can comprise, in particular be, a charging parameter.

In particular in one case or during one instance of carrying out the method, for state and rated variables and possible use time durations, at least one use parameter can be determined and, in particular in another case or during another or, in particular temporally, next instance of carrying out the method, for other state and/or rated variables and/or other possible use time durations, at least one other use parameter can be determined or the at least one use parameter can be determined differently or be different, in particular in a variable manner.

The term “operating” can be used synonymously for the term “using”.

The charger device can be electrical. Additionally or alternatively, the charger device can be integrated, in particular fixedly, into the means of transport.

The rechargeable battery packs, in particular their state and/or rated variables, and/or their possible use time durations, can be different, in particular of different types.

The rechargeable battery packs can be user-exchangeable without tools and/or non-destructively.

The term “user-removable” can be used synonymously for the term “user-exchangeable”.

The term “operation” can be used synonymously for the term “drive”.

The at least one device can be different from the charger device. Additionally or alternatively, the at least one device can be electrically driven, in particular by means of at least one of the rechargeable battery packs, and/or can be a rechargeable battery device. Further additionally or alternatively, the at least one device can be designed for carrying at least one of the rechargeable battery packs. In particular, the at least one device can comprise at least one rechargeable battery pack receptacle, in particular at least one rechargeable battery pack shaft. Further additionally or alternatively, the at least one device can comprise an electric motor drive system, in particular that can be designed to be supplied with electrical drive power by at least one of the rechargeable battery packs. Further additionally or alternatively, the at least one device can be a work device. In particular, the work device can comprise a work tool. Additionally, the electric motor drive system can be designed for, in particular automatically, driving the work tool. Further additionally or alternatively, mobile device can mean that the device, in particular including at least one of the rechargeable battery packs, can have a mass of a maximum of 50 kg (kilograms), in particular of a maximum of 20 kg, in particular of a maximum of 10 kg, in particular of a maximum of 5 kg, and/or of a minimum of 0.5 kg, in particular of a minimum of 1 kg, in particular of a minimum of 2 kg.

The term “portable” can be used synonymously for the term “mobile”.

The term “configured” or “provided” can be used synonymously for the term “designed”.

The term “includes” or “has” can be used synonymously for the term “comprises”.

The ascertaining can be ascertaining values of the state and rated variables.

Additionally or alternatively, the at least one state variable can be, in particular in each case, the most recent. Further additionally or alternatively, the rated variable may or need not be the most recent or the rated variable may typically not change.

The term “attainable” or “predicted” can be used synonymously for the term “possible”.

The ascertaining can comprise, in particular be, detecting.

The ascertaining can be ascertaining values of the possible use time durations. Additionally or alternatively, ascertaining the possible use time durations may or need not be based on the ascertained state and/or rated variables.

The term “occupation time duration” can be used synonymously for the term “use time duration”.

The use time duration can comprise, in particular be, a charging time duration.

The charging can be of a, in particular the, plurality of the rechargeable battery packs.

The determining can take account of at least one value of the at least one use limit. Additionally or alternatively, the determining can take account of use limits, in particular values of the use limits, of the charger device.

The term “limitation” can be used synonymously for the term “limit”.

The charger device can have the at least one use limit or can be limited, in particular by the fact that the means of transport comprises the charger device.

Step b) can be carried out temporally after, with and/or before step a). Additionally or alternatively, step c) can be carried out temporally after step a) and/or step b). Further additionally or alternatively, temporally after step c), the at least one rechargeable battery pack can use the charger device for charging the at least one rechargeable battery pack, in particular in accordance with the at least one use parameter determined. In particular, the method can comprise the following step: using, in particular automatically using and/or charging, the at least one rechargeable battery pack by means of the charger device, in particular in accordance with the at least one use parameter determined. Further additionally or alternatively, the method, in particular step a) and/or step b) and/or step c), can be carried out repeatedly over time, in particular multiply and/or regularly.

In one development of the invention, the at least one rated variable comprises, in particular is, and/or corresponds to: a maximum, in particular maximum permissible, charging and/or drive current, in particular of a minimum of 200 mA (milliamperes), in particular of a minimum of 1 A (ampere), and/or a maximum of 1000 A, in particular a maximum of 200 A, and/or a maximum, in particular maximum permissible, electrical charging and/or drive power, in particular of a minimum of 200 W (watts), in particular of a minimum of 1 kW (kilowatt), and/or a maximum of 10 kW, in particular a maximum of 5 kW, and/or a maximum, in particular maximum permissible, electrical energy content, in particular of a minimum of 1 Wh (watt-hour) and/or a maximum of 8 kWh (kilowatt-hours), in particular 4 kWh, and/or a maximum, in particular maximum permissible, charging and/or drive temperature, in particular 120° C. (degrees Celsius), and/or a minimum, in particular minimum permissible, charging and/or drive temperature, in particular −20° C. The possible use, in particular the possible charging, of the rechargeable battery packs by means of the charger device can be limited by at least one such variable. In particular, the minimum charging and/or drive temperature can be less than the maximum charging and/or drive temperature.

In one development of the invention, the, in particular respective, rechargeable battery packs are for driving mobile devices. Additionally or alternatively, the at least one mobile device is ground- and/or hand-guided, in particular handheld, and/or is a garden, forestry, construction and/or groundwork device, in particular a saw, or a pole-mounted pruner, or a hedge trimmer, or a hedge cutter, or a wood cutter, or a lopper, an angle grinder, or a blower, or a leafblower, or a suction device, or a leaf vacuum, or a cleaning device, or a high-pressure cleaner, or a sweeper, or a sweeping roller, or a sweeping brush, or a lawnmower, or a grass trimmer, or a brushcutter, or a scarifier. The possible use time durations of the rechargeable battery packs, which can be designed for driving at least one such device, for the possible use of the charger device can typically be limited.

In one development of the invention, the means of transport is a vehicle, in particular a land vehicle, in particular a road vehicle, in particular a motor vehicle, in particular an automobile, or a two-wheeler, in particular a motorcycle, or a trailer. By virtue of such a means of transport, the charger device can have the at least one use limit. In particular, the road vehicle can be a cargo bicycle. Additionally or alternatively, the trailer can be a vehicle trailer, in particular with mechanical and/or electrical connection to a vehicle. Further additionally or alternatively, the vehicle can be autonomous. Further additionally or alternatively, a user of the charger device, in particular a gardening and/or landscape design company, can operate the means of transport. Additionally or alternatively, rather than being operated by the user of the at least one mobile device, the means of transport can be operated by an operator of a fleet of the mobile devices, in particular garden, forestry, construction and/or groundwork devices, for instance a retailer and/or a hire company.

In one development of the invention, the at least one use limit comprises, in particular is, and/or corresponds to: a, in particular variable, maximum total charging current and/or a, in particular variable, maximum electrical total charging power for charging the at least one rechargeable battery pack, and/or a, in particular variable, maximum cooling power for cooling the at least one rechargeable battery pack, in particular temporally before and/or with the charging, and/or a, in particular variable maximum heating power for heating the at least one rechargeable battery pack, in particular temporally before the charging, and/or a maximum number, in particular plurality, of power output interfaces, in particular rechargeable battery pack receptacles, in particular rechargeable battery pack shafts in particular for the at least one rechargeable battery pack. The method enables the optimum use of the charger device and/or the optimum charging of the at least one rechargeable battery pack in the cases in which enough charging current and/or charging power and/or cooling power and/or heating power and/or a power output interface cannot be made available to all the rechargeable battery packs by means of the charger device in the possible use time durations. In particular, the total charging current, the total charging power, the cooling power and/or the heating power can be limited by virtue of the fact that the charger device cannot be supplied with electrical power externally by the means of transport permanently over time, in particular during transport by means of the means of transport. Additionally or alternatively, a sum of the total charging power, the cooling power and/or the heating power can be limited. Further additionally or alternatively, the method can comprise the following step: ascertaining the at least one, in particular most recent, use limit, in particular of the total charging current, of the total charging power, of the cooling power and/or of the heating power, and the determining can take account of the at least one use limit ascertained. Further additionally or alternatively, the charger device can comprise at least one, in particular electrical, cooler, in particular a Peltier element and/or a ventilator or a fan, for the cooling and/or at least one, in particular electrical, heater, in particular a radiator, for the heating. Further additionally or alternatively, the power output interface can combine a mechanical interface and an electrical interface. Further additionally or alternatively, the term “rechargeable battery pack charging interface” can be used synonymously for the term “power output interface”. Further additionally or alternatively, the charger device can comprise a kind and a number of chargers (single chargers, multiple chargers), wherein the number of power output interfaces, in particular rechargeable battery pack receptacles, can be determined from the kind and the number of chargers. Further additionally or alternatively, the at least one use limit, in particular the total charging power, can correspond to a charging power of the rechargeable battery packs available in the means of transport and/or to an output power of the occupied power output interfaces, in particular rechargeable battery pack receptacles, and/or of the rechargeable battery packs required at a use location. This can make it possible that the rechargeable battery packs connected to occupied power output interfaces, in particular rechargeable battery pack receptacles, can be charged during transport, in particular a journey, to a next use location. Further additionally or alternatively, in the case of rapid charging processes that are optionally preferably provided, more cooling power may typically be required than in the case of charging processes that may be independent of transport, in particular a journey, of the means of transport. In particular, a charging process when the means of transport is at a standstill can serve as reference here, wherein provision can be made that a connection, in particular an electricity connection, of the means of transport to an external public or private grid can be effected in particular during pause times or overnight.

In one development of the invention, the means of transport comprises at least one, in particular direct, radiation energy conversion device, in particular a solar cell, and/or at least one fuel cell and/or at least one, in particular electrical, energy store, in particular a battery, for supplying the charger device with electrical power. This makes possible the use, in particular the charging, during transport by means of the means of transport and/or makes it possible that the at least one use limit can be variable. In particular, the at least one radiation energy conversion device can be electrical and/or a solar energy conversion device. Additionally or alternatively, the at least one radiation energy conversion device, the at least one fuel cell and/or the at least one energy store can be integrated, in particular fixedly, into the means of transport. Further additionally or alternatively, the at least one energy store, in particular with tool use and/or non-destructively, can be exchangeable or removable and/or retrofitted and/or can be a means of transport rechargeable battery, in particular a vehicle rechargeable battery. Further additionally or alternatively, the at least one energy store can be chargeable, in particular with electrical power from the at least one radiation energy conversion device and/or the at least one fuel cell. Further additionally or alternatively, the at least one energy store can be a temporary store. Further additionally or alternatively, the at least one energy store can be with an operating power of greater than 1.5 kWh. Further additionally or alternatively, the at least one energy store can be different from the rechargeable battery packs. Further additionally or alternatively, the supply can be automatic.

In one development of the invention, the at least one state variable comprises, in particular is, and/or corresponds to: a state of charge (SoC), and/or a temperature. The possible use, in particular the possible charging, of the rechargeable battery packs by means of the charger device can be limited by at least one such variable. In particular, the term “remaining energy” or “energy content” can be used synonymously for the term “state of charge”.

Additionally or alternatively, provision can be made for detecting a temperature of the surroundings of the rechargeable battery packs.

In one configuration of the invention, step c) comprises: determining, in particular respective, cooling time durations for cooling, in particular for the cooling of, and/or, in particular respective heating time durations for heating, in particular for the heating of, the rechargeable battery packs on the basis of the at least one ascertained maximum charging temperature and/or the at least one ascertained minimum charging temperature and also the ascertained temperatures, in particular taking account of the maximum cooling power and/or the maximum heating power, in particular to the extent required; determining, in particular respective, possible charging time durations for charging, in particular for the charging of, the rechargeable battery packs on the basis of the determined cooling time durations, to the extent required, and/or the determined heating time durations, to the extent required, and also the ascertained possible use time durations; determining, in particular respective, possible electrical charging energy amounts of the rechargeable battery packs on the basis of the determined possible charging time durations and also the at least one ascertained maximum charging current and/or the at least one ascertained maximum charging power, in particular and the at least one ascertained maximum electrical energy content and/or the ascertained states of charge and/or taking account of the maximum total charging current and/or the maximum electrical total charging power; and determining the at least one use parameter on the basis of the determined possible charging energy amounts, in particular beginning with the largest charging energy amount and/or taking account of the maximum number of power output interfaces. This enables particularly optimum use of the charger device and/or particularly optimum charging of the at least one rechargeable battery pack. In particular, the determining can be automatic. Additionally or alternatively, the determining can be determining values of the cooling time durations, values of the heating time durations, values of the charging time durations and/or values of the charging energy amounts. Further additionally or alternatively, information as to whether a power output interface, in particular a rechargeable battery pack receptacle, is occupied or is not occupied can be ascertained and transmitted by the rechargeable battery packs. Further additionally or alternatively, the information can be ascertained and transmitted by the charger device, in particular by the chargers and/or a gateway. Further additionally or alternatively, in particular advantageously, the energy store for supplying the charger device can be designed so that or in such a way that the total charging power upon the occupation of all power output interfaces, in particular rechargeable battery pack receptacles, provided in the means of transport cannot exceed the operating power of the energy store. Further additionally or alternatively, the at least one use parameter can be determined in such a way that a charging state and a charging time duration are determined, wherein the charging state can relate to a point in time after the use time duration of the charger device has elapsed. Consequently, determining the at least one use parameter can comprise a charging state forecast. Further additionally or alternatively, the charging time duration t can be determined as: t=f(rechargeable battery type, charger type, SoC, SoH (%), cooling time duration+delta_SoC, heating time duration+delta_SoC, factor_charging mode (%)), where SoH stands for “State of Health”. Further additionally or alternatively, the charging time duration t can be determined, in particular preferably, on the basis of or taking account of an, in particular the and/or ascertained maximum, electrical charging power for charging the at least one rechargeable battery pack and an, in particular maximum, electrical charging power of a charger type of the charger provided for charging: t=f(charging power_rechargeable battery, charging power_charger, SoC, SoH (%), cooling time duration+delta_SoC, heating time duration+delta_SoC, factor_charging mode (%)). Further additionally or alternatively, the cooling time duration of the rechargeable battery pack can be dependent on a temperature difference between the temperature of the rechargeable battery pack and the temperature of the surroundings. Further additionally or alternatively, the cooling time duration can be dependent on the available charger type, thus on the rechargeable battery pack-charger combination. By way of example, different chargers can comprise different types of fan. Further additionally or alternatively, the heating time duration can be dependent on the temperature of the rechargeable battery pack and a current intensity. Further additionally or alternatively, heating can be provided only until the beginning of the charging. In particular, during the charging, provision can be made for using the power loss of the charger device, which can be converted into thermal energy. This can make it possible to determine the charging power depending on the cooling or heating power. In particular, it is possible to avoid a situation in which charging power can no longer be available on account of a cooling or heating power. Further additionally or alternatively, the cooling or heating power can be expended for preconditioning the rechargeable battery pack prior to a use of the rechargeable battery pack.

In one development of the invention, step c) comprises: determining the at least one use parameter on the basis of, in particular only, a, in particular a single, optimization criterion. The optimization criterion is a, in particular the, largest charging energy amount, in particular a largest value of the charging energy amount, of the at least one rechargeable battery pack. This enables particularly optimum use of the charger device and/or particularly optimum charging of the at least one rechargeable battery pack. In other words: determining the at least one use parameter so that as much energy as possible, in particular in total, can be charged into the rechargeable battery packs available in the means of transport. In particular, the optimization problem can be solved by determining 1−(P(T_rechargeable battery, AL in %)*SoC(rechargeable battery)) so that a value which tends to 1 is obtained. P(T_rechargeable battery, AL in %) indicates the charging power for a rechargeable battery pack-charger combination. In particular, charging processes for power output interfaces, in particular rechargeable battery pack receptacles, of individual chargers can be started and stopped on the basis thereof. In particular, the starting and the stopping can correspond, in particular equate, to switching on and switching off the power output interfaces, in particular the rechargeable battery pack receptacles. Additionally or alternatively, the starting and the stopping can be different from a supervision, in particular an open-loop control and/or a closed-loop control, of the charging process.

In one development, in particular one configuration, of the invention, the at least one use parameter comprises, in particular is, and/or corresponds to: the at least one rechargeable battery pack, in particular at least one identification of the at least one rechargeable battery pack, for using the charger device, and/or at least one cooling power for cooling, in particular for the cooling of, and/or at least one heating power for heating, in particular for the heating of, the at least one rechargeable battery pack, and/or at least one charging current and/or at least one electrical charging power for charging, in particular for the charging of, the at least one rechargeable battery pack. In particular, the at least one use parameter, in particular comprising the electrical charging power, can be determined in such a way that the charging power for the at least one rechargeable battery pack can correspond, in particular equate, to the total charging power.

Additionally or alternatively, the at least one use parameter can be determined in such a way that a capacity utilization of the rechargeable battery packs can be associated with a uniform wear. In particular, provision can be made for adapting the cooling power and/or the heating power and/or the charging current so that an efficient, uniform use of the rechargeable battery packs can result. In particular, the cooling power and/or the heating power can be applied by an apparatus for the air-conditioning of the means of transport and/or by the charger device, in particular the chargers.

In one development of the invention, the method comprises the following step: d) outputting user-perceivable information about the at least one determined use parameter, in particular the at least one rechargeable battery pack for using the charger device. This enables a user to perceive which of the rechargeable battery packs the user can exchange. In particular, the outputting can be automatic, optical, acoustic and/or haptic and/or outputting of a content of the information and/or of the use parameter. In particular, the optical outputting can comprise displaying. Additionally or alternatively, the haptic outputting can comprise vibrating. Further additionally or alternatively, at the use location, rechargeable battery packs no longer required and/or rechargeable battery packs selected or determined for the charging can output or signal, e.g. optically or acoustically, that they can be provided for being received in the means of transport and for being connected to the power output interface, in particular for being inserted into the rechargeable battery pack receptacle. Further additionally or alternatively, in particular analogously, the rechargeable battery packs that are to be removed from the means of transport and are required at the use location can output or signal that they can be removed from the means of transport. Further additionally or alternatively, provision can be made for the user-perceivable information to be able to be transmitted or communicated and output to a user interface.

In one development of the invention, step a) comprises: wirelessly transmitting the at least one state variable, in particular from at least one of the rechargeable battery packs, in particular in a manner not using the charger device. Consequently, the ascertaining can be simple. In particular, the term “wire-free” can be used synonymously for the term “wireless”. Additionally or alternatively, the transmitting can be automatic and/or transmitting at least one value of the at least one state variable and/or by means of a gateway. In particular, the gateway can be with a position determining apparatus and/or installed in the means of transport and/or at use and/or storage locations. Further additionally or alternatively, the following can be remote from the means of transport: databases, servers, clouds (e.g. backend, route planner, traffic information), cloud-to-cloud interfaces and cloud-to-cloud communication. By way of example, provision can be made for a digital twin of the means of transport and of the use locations to be able to be kept available at a distance (remote) from the means of transport. In particular, the digital twin can be designed as a model for the use or the operation of the charger device. In particular, the model can at least comprise or include: an average power P (Wh/time), which can be an average charging power or an average energy feed (absolute value Wh/time positive) or an average drive or discharging power or an average energy consumption (absolute value Wh/time negative), of the respective rechargeable battery pack, and/or a geoposition, a rechargeable battery pack designator (e.g. a rechargeable battery pack type) and/or a unique identification or identifier (e.g. an ID) of the respective rechargeable battery pack, and/or the SoH, the temperature (T), the state of charge (SoC) of the respective rechargeable battery pack, and/or a number of available rechargeable battery packs in the means of transport. Further additionally or alternatively, the model can comprise or include the kind and the number of the chargers, a number of rechargeable battery packs able to be received in the means of transport, which can correspond, in particular equate, in particular to a number of unoccupied power output interfaces, in particular rechargeable battery pack receptacles, and/or a temperature of the surroundings.

In one development of the invention, at least one of the possible use time durations comprises, in particular is, and/or corresponds to: a possible residence time duration of at least one of the rechargeable battery packs onboard the means of transport, in particular a possible transport time duration of the means of transport, in particular from an initial location or departure location or start location, to a possible drive location or arrival location or destination location or use location of at least one of the rechargeable battery packs. By virtue of such a use time duration, the use of the charger device can be for charging the at least one rechargeable battery pack when the at least one rechargeable battery pack cannot be used anyway. In particular, the means of transport can be provided for supplying use locations situated at different places with rechargeable battery packs. In particular, the use locations can be acquired by a user of the mobile devices, in particular a fleet manager and/or a driver, and/or an operator of the means of transport by means of a user interface. Additionally or alternatively, at the use locations, at least one user of the mobile devices or a group of users of the mobile devices, in particular a team, can work with in each case at least one mobile device that can be supplied by at least one of the rechargeable battery packs. Further additionally or alternatively, provision can be made for acquiring the number of users at the use locations and the demand for mobile devices at the use locations for performing work tasks by means of the user interface. In particular, the geoposition of the rechargeable battery packs in this case can correspond, in particular equate, to the use location. Further additionally or alternatively, for the user or the group on the basis of work tasks to be performed and on the basis of the mobile devices provided therefor, it is possible to determine an energy demand at the use location. In particular, the energy demand can be repeatedly determined anew. Additionally or alternatively, on the basis of the determination, the energy demand, which can correspond, in particular equate, to a number of rechargeable battery packs of different types, can be transmitted or communicated to a gateway and/or a server, which can provide a database, and/or a model. Further additionally or alternatively, the states of charge of the rechargeable battery packs at the use location can change depending on work progress. In particular, the rechargeable battery pack which is intended to be charged can be ascertained repeatedly and/or regularly for the rechargeable battery packs. In particular, a rechargeable battery pack to be charged can correspond, in particular equate, to a rechargeable battery pack not required (or no longer required) at the use location, which rechargeable battery pack can be received by the means of transport. In particular, the kind and the number of rechargeable battery packs no longer required can be transmitted or communicated to the gateway and/or the database and/or the model. In particular, the means of transport can comprise the gateway. Additionally or alternatively, the transmitting or the communicating can make it possible that steps b) and c) can be carried out particularly well. Further additionally or alternatively, the position of the means of transport can be regularly determined and updated. In particular, a transport route, in particular a travel route, and a transport time duration, in particular a travel time duration, can be determined in each case for the next use location on the basis of the present position of the means of transport. In particular, the determination of a travel route and of a travel duration can be performed by means of conventional methods for route planning taking account of traffic information. By way of example, cloud-to-cloud interfaces are used in this case. Additionally or alternatively, the travel route can be a travel route from a location A to a location B. Additionally or alternatively, provision can be made for the travel route to be able to be a travel route from an initial location, in particular a storage location of the rechargeable battery packs and/or a workshop, to a use location, and vice versa, and/or a travel route from an arbitrary use location N to a further use location M. Further additionally or alternatively, on the basis of the travel route and the travel time duration, an anticipated arrival time for the next use location in each case can be determined and transmitted or communicated. In particular, the anticipated arrival time and the number of rechargeable battery packs corresponding to the energy demand can be transmitted or communicated to a gateway and/or the user, in particular a foreman, and/or the group at the respective use location. Additionally or alternatively, the anticipated arrival time and the number of rechargeable battery packs corresponding to the energy demand can be stored in a database and can be retrievable for further users of the charger device, in particular a fleet manager. Further additionally or alternatively, provision can be made for fully charged and charging rechargeable battery packs to be able to be in the means of transport, in particular the vehicle. Further additionally or alternatively, the charging state prediction can indicate the charging state that can correspond, in particular equate, to the anticipated arrival time at the next use location in each case (example prediction: “At the destination location, you will have available 2 kWh of energy in 7 rechargeable battery packs with <80% SoC”). In particular, the charging state prediction can enable an estimation of whether the energy demand can be met at the next use location in each case. Further additionally or alternatively, it can be provided that for ascertaining the use time durations, use locations are determined on the basis of a number of predefined use locations, to which respective work tasks to be performed can be assigned. In particular on the basis of the work tasks to be performed, it is possible to determine the energy demand at the respective possible use location. In particular on the basis of the energy demand, it is possible to determine the at least one use parameter in accordance with step c), at least one maximum charging time duration (e.g. in the form of a charging duration prediction) for the number of rechargeable battery packs corresponding to the energy demand. In particular, the number of rechargeable battery packs can be available in the means of transport. Additionally or alternatively, a travel route and a travel time duration can be determined for each use location from the number of predefined use locations on the basis of the present position of the means of transport. In particular, a use location can be ascertained from the number of predefined use locations by comparing the maximum charging time duration with the travel time duration. In particular, the determination of the use location can accordingly include the fact that at the anticipated arrival time the rechargeable battery packs have been charged so as to enable the energy demand at the use location to be met. Additionally or alternatively, the charging state prediction can be based on the travel time duration that can correspond, in particular equate, to the use time durations. In other words: optimization problem “Determining the next location”.

The system according to the invention is designed for determining, in particular for the determining of, at least one, in particular the at least one, use parameter for, in particular the, at least one rechargeable battery pack for using, in particular for the using of, a, in particular the, charger device for charging, in particular for the charging of, in particular the, user-exchangeable rechargeable battery packs for driving at least one, in particular the at least one, mobile device. A, in particular the, means of transport comprises the charger device. The system comprises: an ascertaining device and a determining device. The ascertaining device is designed: for ascertaining, in particular for the ascertaining of, in particular the, state and rated variables of the rechargeable battery packs relating to a possible, in particular the possible, charging of the rechargeable battery packs by means of the charger device, and for ascertaining, in particular for the ascertaining of, in particular the, possible use time durations of the rechargeable battery packs for possibly using, in particular for the possible using of, the charger device relating to a possible, in particular the possible, charging of the rechargeable battery packs by means of the charger device. The determining device is designed: for determining, in particular for the determining of, the at least one use parameter for, in particular the, at least one of the rechargeable battery packs for using, in particular for the using of, the charger device for charging, in particular for the charging of, the at least one rechargeable battery pack by means of the charger device by linking, in particular the linking of, the ascertained state and rated variables and the ascertained possible use time durations taking account of at least one, in particular the at least one, use limit of the charger device. In particular, the system can be designed for, in particular automatically, carrying out a, in particular the, method as mentioned above. Additionally or alternatively, the system, the ascertaining device and/or the determining device can be electrical.

In one development of the invention, the system comprises: the rechargeable battery packs, the charger device, the at least one mobile device and/or the means of transport.

Other objects, advantages and novel features of the present invention will become apparent from the following detailed description of one or more preferred embodiments when considered in conjunction with the accompanying drawings.

### BRIEF DESCRIPTION OF THE DRAWINGS

FIG. 1 schematically shows an exemplary method according to the invention and an exemplary system according to the invention for determining at least one use parameter for at least one rechargeable battery pack for using a charger device for charging user-exchangeable rechargeable battery packs for driving at least one mobile device, wherein a means of transport comprises the charger device;

FIG. 2 schematically shows details in the form of steps of the method from FIG. 1 carried out by means of the system from FIG. 1;

FIG. 3 schematically shows details in the form of devices of the system from FIG. 1;

FIG. 4 schematically shows further details in the form of devices of the system from FIG. 1;

FIG. 5 schematically shows the method from FIG. 1 comprising a charging duration prediction on the basis of an energy demand for a work deployment; and

FIG. 6 schematically shows the method from FIG. 1 comprising determining cooling time durations for cooling, heating time durations for heating and possible charging time durations for charging the rechargeable battery packs.

### DETAILED DESCRIPTION OF THE DRAWINGS

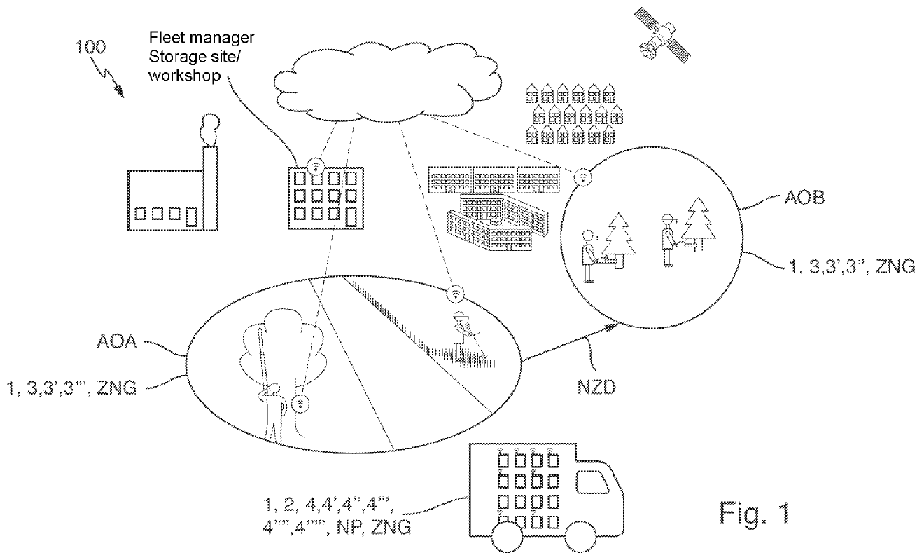

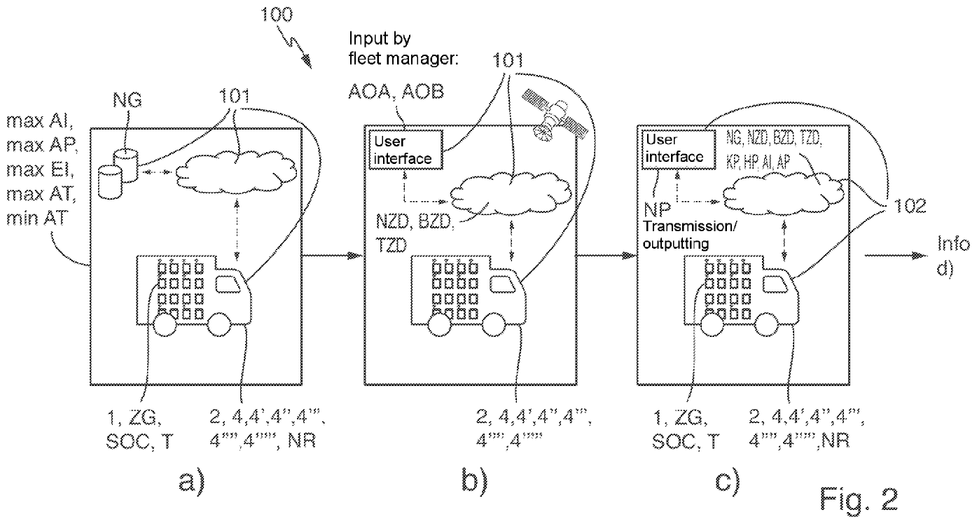

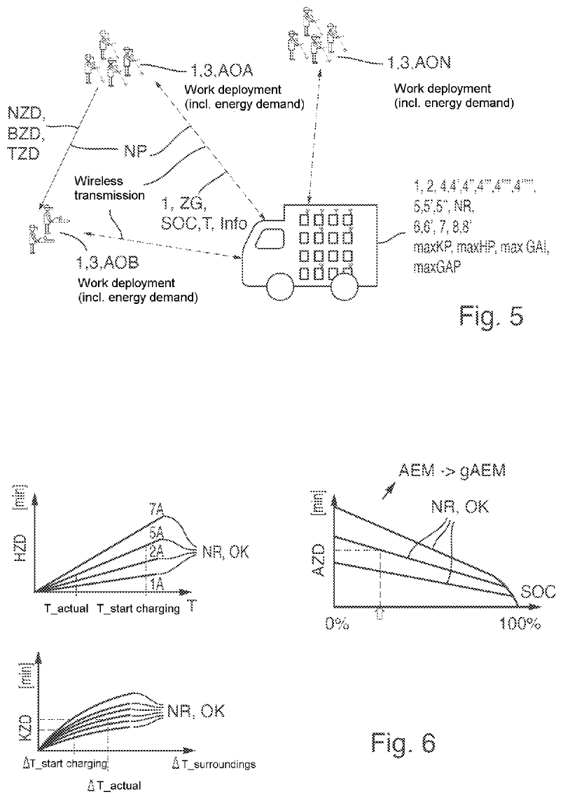

FIGS. 1 to 6 show a system 100 and a method for determining at least one use parameter NP for at least one rechargeable battery pack 1 for using a charger device 2 for charging user-exchangeable rechargeable battery packs 1 for driving at least one mobile device 3. A means of transport 4 comprises the charger device 2.

The system 100 comprises: an ascertaining device 101 and a determining device 102. The ascertaining device 101 is designed: for ascertaining state and rated variables ZNG of the rechargeable battery packs 1 relating to a possible charging of the rechargeable battery packs 1 by means of the charger device 2, and for ascertaining possible use time durations NZD of the rechargeable battery packs 1 for possibly using the charger device 2 relating to a possible charging of the rechargeable battery packs 1 by means of the charger device 2, in particular ascertains same. The determining device 102 is designed: for determining the at least one use parameter NP for at least one of the rechargeable battery packs 1 for using the charger device 2 for charging the at least one rechargeable battery pack 1 by means of the charger device 2 by linking the ascertained state and rated variables ZNG and the ascertained possible use time durations NZD taking account of at least one use limit NR of the charger device 2, in particular determines same.

The method comprises the following steps: a) ascertaining the state and rated variables ZNG of the rechargeable battery packs 1 relating to the possible charging of the rechargeable battery packs 1 by means of the charger device 2, in particular by means of the ascertaining device 101; b) ascertaining the possible use time durations NZD of the rechargeable battery packs 1 for the possible using of the charger device 2 relating to the possible charging of the rechargeable battery packs 1 by means of the charger device 2, in particular by means of the ascertaining device 101; c) determining the at least one use parameter NP for the at least one of the rechargeable battery packs 1 for the using of the charger device 2 for the charging of the at least one rechargeable battery pack 1 by means of the charger device 2 by linking the ascertained state and rated variables ZNG and the ascertained possible use time durations NZD taking account of the at least one use limit NR of the charger device 2, in particular by means of the determining device 102.

In detail, the system 100 comprises: the rechargeable battery packs 1, the charger device 2, the at least one mobile device 3 and/or the means of transport 4.

Furthermore, the at least one rated variable NG comprises, in particular is, and/or corresponds to: a maximum charging and/or drive current maxAI, in particular of a minimum of 200 mA, in particular of a minimum of 1 A, and/or a maximum of 1000 A, in particular a maximum of 200 A, and/or a maximum electrical charging and/or drive power maxAP, in particular of a minimum of 200 W, in particular of a minimum of 1 kW, and/or a maximum of 10 kW, in particular a maximum of 5 kW, and/or a maximum electrical energy content maxEI, in particular of a minimum of 1 Wh and/or a maximum of 8 kWh, in particular 4 kWh, and/or a maximum charging and/or drive temperature maxAT, in particular 120° C., and/or a minimum charging and/or drive temperature minAT, in particular −20° C.

Additionally or alternatively, the rechargeable battery packs 1 are designed, in particular in each case, for the driving with a rated voltage of a minimum of 9 V (volts), in particular a minimum of 18 V, and/or a maximum of 100 V, in particular a maximum of 72 V, in particular 36 V.

Moreover, the rechargeable battery packs 1 are for driving mobile devices 3.

Additionally or alternatively, the at least one mobile device 3 is ground- and/or hand-guided, in particular handheld, and/or is a garden, forestry, construction and/or groundwork device 3′, in particular a saw 3″, or a pole-mounted pruner 3″ or a hedge trimmer, or a hedge cutter, or a wood cutter, or a lopper, an angle grinder, or a blower, or a leafblower, or a suction device, or a leaf vacuum, or a cleaning device, or a high-pressure cleaner, or a sweeper, or a sweeping roller, or a sweeping brush, or a lawnmower, or a grass trimmer, or a brushcutter, or a scarifier.

Further the means of transport 4 is a vehicle 4′, in particular a land vehicle 4″, in particular a road vehicle 4′″, in particular a motor vehicle 4″″, in particular an automobile 4″ or a two-wheeler, in particular a motorcycle, or a trailer.

In addition, the at least one use limit NR comprises, in particular is, and/or corresponds to: a, in particular variable, maximum total charging current maxGAI and/or a, in particular variable, maximum electrical total charging power maxGAP for charging the at least one rechargeable battery pack 1, and/or a, in particular variable, maximum cooling power maxKP for cooling the at least one rechargeable battery pack 1 and/or a, in particular variable, maximum heating power maxHP for heating the at least one rechargeable battery pack 1, and/or a maximum number, in particular plurality, of power output interfaces 5, in particular rechargeable battery pack receptacles 5′, in particular rechargeable battery pack shafts 5″, in particular for the at least one rechargeable battery pack 1.

Furthermore, the means of transport 4 comprises at least one, in particular direct, radiation energy conversion device 6, in particular a solar cell 6′, and/or at least one fuel cell 7 and/or at least one, in particular electrical, energy store 8, in particular a battery 8′, for supplying the charger device 2 with electrical power.

In addition, the at least one state variable ZG comprises, in particular is, and/or corresponds to: a state of charge SOC, and/or a temperature T.

Further, step c) comprises: determining cooling time durations KZD for cooling and/or heating time durations HZD for heating the rechargeable battery packs 1 on the basis of the at least one ascertained maximum charging temperature maxAT and/or the at least one ascertained minimum charging temperature minAT and also the ascertained temperatures T, in particular taking account of the maximum cooling power maxKP and/or the maximum heating power maxHP, in particular by means of the determining device 102; determining possible charging time durations AZD for charging the rechargeable battery packs 1 on the basis of the determined cooling time durations KZD and/or the determined heating time durations HZD and also the ascertained possible use time durations NZD, in particular by means of the determining device 102; determining possible electrical charging energy amounts AEM of the rechargeable battery packs 1 on the basis of the determined possible charging time durations AZD and also the at least one ascertained maximum charging current maxAI and/or the at least one ascertained maximum charging power maxAI, in particular and the at least one ascertained maximum electrical energy content maxEI and/or the ascertained states of charge SOC and/or taking account of the maximum total charging current maxGAI and/or the maximum electrical total charging power maxGAP, in particular by means of the determining device 102; determining the at least one use parameter NP on the basis of the determined possible charging energy amounts AEM, in particular beginning with the largest charging energy amount gAEM and/or taking account of the maximum number of power output interfaces 5 in particular by means of the determining device 102.

In addition, step c) comprises: determining the at least one use parameter NP on the basis of an optimization criterion OK. The optimization criterion OK is a, in particular the, largest charging energy amount gAEM of the at least one rechargeable battery pack 1.

Furthermore, the at least one use parameter NP comprises, in particular is, and/or corresponds to: the at least one rechargeable battery pack 1 for using the charger device 2, and/or at least one cooling power KP for cooling and/or at least one heating power HP for heating the at least one rechargeable battery pack 1, and/or at least one charging current AI and/or at least one electrical charging power AP for charging the at least one rechargeable battery pack 1.

Moreover, the method comprises the following step: d) outputting user-perceivable information Info about the at least one determined use parameter NP, in particular the at least one rechargeable battery pack 1 for using the charger device 2, in particular by means of the at least one rechargeable battery pack 1, the charger device 2, the means of transport 4 and/or a user interface of the system 100, in particular in the form of a smartphone and/or a tablet.

Further, step a) comprises: wirelessly transmitting the at least one state variable ZG, in particular from at least one of the rechargeable battery packs 1, in particular in a manner not using the charger device 2.

In addition, at least one of the possible use time durations NZD comprises, in particular is, and/or corresponds to: a possible residence time duration BZD of at least one of the rechargeable battery packs 1 onboard the means of transport 4, in particular a possible transport time duration TZD of the means of transport 4, in particular from an initial location AOA, to a possible drive location AOB of at least one of the rechargeable battery packs 1.

In the exemplary embodiment shown, the system 100 comprises a minimum of nine rechargeable battery packs 1 and/or a maximum of one hundred rechargeable battery packs 1, in particular in a manner corresponding, in particular equating, to an energy of a minimum of 15 kWh and/or a maximum of 50 kWh that is available for driving or for outputting to the mobile devices 3. Additionally or alternatively, the charger device 2 comprises only a single power output interface 5 or at least two, in particular at least five, in particular at least ten, in particular at least twenty, in particular at least fifty, power output interfaces 5.

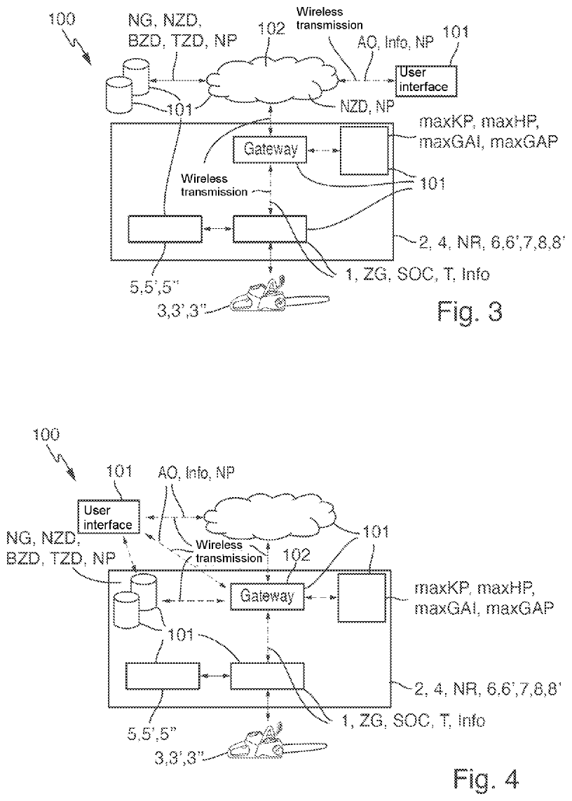

In FIG. 3, determining the at least one use parameter NP is performed remote from the means of transport 4. In FIG. 4, determining the at least one use parameter NP is performed locally in the means of transport 4, in particular wherein a cloud link may be e.g. for route planning and/or for traffic information.

In one exemplary embodiment, the charger device 2 can comprise only a single power output interface 5, but two rechargeable battery packs 1 with different state and rated variables ZNG may need to be charged. In particular, a temperature T of one of the rechargeable battery packs 1 may be above the maximum charging and drive temperature maxAT, such that said one rechargeable battery pack 1 would need to be cooled at a time before the possible charging. A temperature T of another of the rechargeable battery packs 1 may be below the maximum charging and drive temperature maxAT and above the minimum charging and/or drive temperature minAT, such that the other rechargeable battery pack 1 could be charged directly. However, a maximum electrical charging and/or drive power maxAP of one rechargeable battery pack 1 may be above a maximum electrical charging and/or drive power maxAP of the other rechargeable battery pack 1. Moreover, possible use time durations NZD of the two rechargeable battery packs 1 may be identical. By linking the ascertained state and rated variables ZNG and the ascertained possible use time durations NZD, it is possible, taking account of, in particular only, the at least one, in particular single, use limit NR in the form of the single power output interface 5 on the basis of the optimization criterion OK, to determine, in particular only, the at least one, in particular single, use parameter NP as, in particular only, one rechargeable battery pack 1 in one case of long possible use time durations NZD and the other rechargeable battery pack 1 in another case of short possible use time durations NZD. This makes possible the largest charging energy amount gAEM of, in particular only, one rechargeable battery pack 1 in one case and the other rechargeable battery pack 1 in the other case.

In a further exemplary embodiment, the two rechargeable battery packs 1 with the different state and rated variables ZNG may need to be charged and the charger device 2 can comprise at least two power output interfaces 5. By linking the ascertained state and rated variables ZNG and the ascertained possible use time durations NZD, it is possible, taking account of the use limits NR in the form of a maximum electrical total charging power maxGAP and a maximum cooling power maxKP on the basis of the optimization criterion OK, to determine the at least one use parameter NP as a cooling power KP for cooling and one electrical charging power AP for charging one rechargeable battery pack 1, in particular and another electrical charging power AP for, in particular simultaneously, charging the other rechargeable battery pack 1, in one case of long possible use time durations NZD and, in particular only, as a, in particular single, electrical charging power AP for charging, in particular only, the other rechargeable battery pack 1 in another case of short possible use time durations NZD. This enables the largest charging energy amount gAEM of one rechargeable battery pack 1, in particular and of the other rechargeable battery pack 1, in one case and of the other rechargeable battery pack 1 in the other case.

As made clear by the exemplary embodiments shown and explained above, the invention provides an advantageous method and an advantageous system, in particular in each case, for determining at least one use parameter for at least one rechargeable battery pack for using a charger device for charging user-exchangeable rechargeable battery packs for driving at least one mobile device, wherein a means of transport comprises the charger device, in particular wherein the method and the system, in particular in each case, have improved properties.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof

What is claimed is:

1. A method for determining at least one use parameter for at least one rechargeable battery pack for using a charger device that charges user-exchangeable rechargeable battery packs for driving at least one mobile device, wherein a means of transport comprises the charger device, the method comprising the steps of:
a) ascertaining state and rated variables of the rechargeable battery packs relating to a possible charging of the rechargeable battery packs via the charger device;
b) ascertaining possible use time durations of the rechargeable battery packs for possibly using the charger device relating to a possible charging of the rechargeable battery packs via the charger device; and
c) determining the at least one use parameter for at least one of the rechargeable battery packs for using the charger device to charge the at least one rechargeable battery pack via the charger device by linking the ascertained state and rated variables and the ascertained possible use time durations taking into account at least one use limit of the charger device.

2. The method according to claim 1,
wherein at least one rated variable comprises and/or corresponds to:
a maximum charging and/or drive current, and/or
a maximum electrical charging and/or drive power, and/or
a maximum electrical energy content, and/or
a maximum charging and/or drive temperature, and/or
a minimum charging and/or drive temperature.

3. The method according to claim 2, wherein at least one of:
the maximum charging and/or drive current is one of: a minimum of 200 mA, a minimum of 1 A, a maximum of 1000 A or a maximum of 200 A,
the maximum electrical charging and/or drive power is one of: a minimum of 200 W, a minimum of 1 kW, a maximum of 10 kW, or a maximum of 5 kW,
the maximum electrical energy content is one of: a minimum of 1 Wh, a maximum of 8 kWh, or is 4 kWh,
the maximum charging and/or drive temperature is 120° C., or
the minimum charging and/or drive temperature is −20° C.

4. The method according to claim 1,
wherein the rechargeable battery packs are for driving mobile devices, and/or
wherein the at least one mobile device is ground- and/or hand-guided and/or is a garden, forestry, construction and/or groundwork device comprising one of: a saw, a pole-mounted pruner, a hedge trimmer, a hedge cutter, a wood cutter, a lopper, an angle grinder, a blower, a leafblower, a suction device, a leaf vacuum, a cleaning device, a high-pressure cleaner, a sweeper, a sweeping roller, a sweeping brush, a lawnmower, a grass trimmer, a brushcutter, or a scarifier.

5. The method according to claim 1,
wherein the means of transport is a vehicle, a land vehicle, a road vehicle, a motor vehicle, an automobile, a two-wheeler vehicle, or a trailer.

6. The method according to claim 1,
wherein the at least one use limit of the charger device comprises and/or corresponds to:
a variable maximum total charging current and/or a variable maximum electrical total charging power for charging the at least one rechargeable battery pack, and/or
a variable maximum cooling power for cooling the at least one rechargeable battery pack and/or a variable maximum heating power for heating the at least one rechargeable battery pack, and/or
a maximum number of power output interfaces.

7. The method according to claim 1,
wherein the power output interfaces are rechargeable battery pack receptacles and/or rechargeable battery pack shafts.

8. The method according to claim 1, wherein the means of transport comprises one or more of:
a radiation energy conversion device, a fuel cell, or an energy store, for supplying the charger device with electrical power.

9. The method according to claim 1, wherein
the radiation energy conversion device is a solar cell, and/or
the energy store is a battery.

10. The method according to claim 2,
wherein the at least one state variable comprises and/or corresponds to:
a state of charge, and/or
a temperature.

11. The method according to claim 10,
wherein step c) comprises:
determining cooling time durations for cooling and/or heating time durations for heating the rechargeable battery packs on the basis of the ascertained maximum charging temperature and/or the ascertained minimum charging temperature and also the ascertained temperature, taking account of a maximum cooling power and/or a maximum heating power;
determining possible charging time durations for charging the rechargeable battery packs on the basis of the determined cooling time durations and/or the determined heating time durations and also the ascertained possible use time durations;
determining possible electrical charging energy amounts of the rechargeable battery packs on the basis of the determined possible charging time durations and also the ascertained maximum charging current and/or the ascertained maximum charging power, and the ascertained maximum electrical energy content and/or the ascertained states of charge and/or taking account of a maximum total charging current and/or a maximum electrical total charging power, and
determining the at least one use parameter on the basis of the determined possible charging energy amounts, beginning with a largest charging energy amount and/or taking account of a maximum number of power output interfaces.

12. The method according to claim 1,
wherein step c) comprises: determining the at least one use parameter on the basis of an optimization criterion, wherein
the optimization criterion is a largest charging energy amount of the at least one rechargeable battery pack.

13. The method according to claim 5,
wherein the at least one use parameter comprises and/or corresponds to one or more of:
the at least one rechargeable battery pack for using the charger device,
at least one cooling power for cooling and/or at least one heating power for heating the at least one rechargeable battery pack, or
at least one charging current and/or at least one electrical charging power for charging the at least one rechargeable battery pack.

14. The method according to claim 1, the method further comprising the step of:
d) outputting user-perceivable information about the at least one determined use parameter for using the charger device.

15. The method according to claim 1,
wherein step a) comprises: wirelessly transmitting the at least one state variable from at least one of the rechargeable battery packs in a manner not using the charger device.

16. The method according to claim 1,
wherein at least one of the possible use time durations comprises and/or corresponds to:
a possible residence time duration of at least one of the rechargeable battery packs onboard the means of transport.

17. The method according to claim 1,
wherein at least one of the possible use time durations comprises and/or corresponds to:
a possible transport time duration of the means of transport to a possible drive location of at least one of the rechargeable battery packs.

18. A system for determining at least one use parameter for at least one rechargeable battery pack for using a charger device that charges user-exchangeable rechargeable battery packs for driving at least one mobile device, wherein a means of transport comprises the charger device, comprising:
(a) an ascertaining device, wherein the ascertaining device is designed to:
ascertain state and rated variables of the rechargeable battery packs relating to a possible charging of the rechargeable battery packs via the charger device, and
ascertain possible use time durations of the rechargeable battery packs for possibly using the charger device relating to a possible charging of the rechargeable battery packs via the charger device; and
(b) a determining device, wherein the determining device is designed to:
determine the at least one use parameter for at least one of the rechargeable battery packs for using the charger device that charges the at least one rechargeable battery pack via the charger device by linking the ascertained state and rated variables and the ascertained possible use time durations taking into account at least one use limit of the charger device.

19. The system according to claim 18, further comprising one or more of:
the rechargeable battery packs,
the charger device,
the at least one mobile device or,
the means of transport.
